(19) United States
(12) Patent Application Publication
(10) Pub. No.: US 2025/0273639 A1
(43) Pub. Date: Aug. 28, 2025

(54) SEMICONDUCTOR PACKAGE

(71) Applicant: Samsung Electronics Co., Ltd., Suwon-si (KR)

(72) Inventors: Changui Hong, Suwon-si (KR); Kwangho Park, Suwon-si (KR); Jungeun Koo, Suwon-si (KR); Yongjin Seol, Suwon-si (KR); Dongchul Yang, Suwon-si (KR); Sangwoong Lee, Suwon-si (KR); Deokhee Han, Suwon-si (KR)

(21) Appl. No.: 18/817,551

(22) Filed: Aug. 28, 2024

(30) Foreign Application Priority Data
Feb. 26, 2024 (KR) 10-2024-0026900

(51) Int. Cl. H01L 25/16; H01L 23/00; H01L 23/498; H01L 23/538; H10B 80/00

(52) U.S. Cl. CPC H01L 25/162; H01L 23/49838; H01L 23/538; H01L 25/165; H10B 80/00; H01L 24/16; H01L 24/32; H01L 24/48; H01L 2224/16148; H01L 2224/16227; H01L 2224/32145; H01L 2224/32225; H01L 2224/48227; H01L 2924/1431; H01L 2924/1433; H01L 2924/1436; H01L 2924/19041; H01L 2924/3511

(57) ABSTRACT

A semiconductor package may include a lower substrate having an upper surface including first, second, and third regions and a lower interconnection layer; lower connection structures below the lower substrate; a first semiconductor chip on the second region and electrically connected to the lower interconnection layer; a second semiconductor chip adjacent to the first semiconductor chip on the second region and electrically connected to the first semiconductor chip; intermediate connection structures on the lower substrate and electrically connected to the lower interconnection layer; an upper substrate on the first semiconductor chip and the intermediate connection structures; a third semiconductor chip overlapping the first semiconductor chip; and a fourth semiconductor chip spaced apart from the third semiconductor chip and overlapping the third region, wherein a density of the intermediate connection structures on the first and third regions is greater than a density of the intermediate connection structures on the second region.

### CROSS-REFERENCE TO RELATED APPLICATION(S)

This application claims benefit of priority under 35 U.S.C. § 119 to Korean Patent Application No. 10-2024-0026900, filed on Feb. 26, 2024, in the Korean Intellectual Property Office, the disclosure of which is incorporated herein by reference in its entirety.

### BACKGROUND

The present disclosure relates to a semiconductor package. More specifically, the present disclosure relates to a semiconductor package having improved integration and electrical characteristics.

With the development of the electronics industry, demand for higher functionality, higher speed, and smaller electronic components is increasing. According to this trend, a system in package (SIP), requiring complexity and multifunctionality in terms of functionality, has been studied. In terms of structure, a package on package (POP) structure is being developed in which multiple semiconductor chips are stacked and mounted on a package substrate, or another semiconductor package is stacked on a semiconductor package. In particular, research is being actively conducted to simultaneously secure miniaturization and reliability in such semiconductor packages.

### SUMMARY

An aspect of the present disclosure is to provide a semiconductor package having improved electrical characteristics between semiconductor chips.

Another aspect of the present disclosure is to provide a semiconductor package having a system-in-package structure with improved integration.

However, the object of the present disclosure is not limited to the above-described objects, and may be variously extended without departing from the spirit and scope of the present disclosure.

According to an example embodiment of the present disclosure, a semiconductor package may include: a lower substrate having an upper surface including a first region, a second region, and a third region sequentially arranged in a first direction, and including a lower interconnection layer; lower connection structures disposed below the lower substrate; a first semiconductor chip disposed on the second region and electrically connected to the lower interconnection layer; a second semiconductor chip adjacent to the first semiconductor chip on the second region and electrically connected to the first semiconductor chip; intermediate connection structures disposed on the lower substrate and electrically connected to the lower interconnection layer; an upper substrate disposed on the first semiconductor chip and the intermediate connection structures; a third semiconductor chip overlapping the first semiconductor chip on the upper substrate in a perpendicular direction, which is perpendicular to the first semiconductor chip; and a fourth semiconductor chip spaced apart from the third semiconductor chip on the upper substrate in the first direction and overlapping the third region in the perpendicular direction, wherein a density of the intermediate connection structures disposed on the first region and the third region may be greater than a density of the intermediate connection structures disposed on the second region.

According to an example embodiment of the present disclosure, a semiconductor package may include: a lower substrate including a lower interconnection layer; lower connection structures disposed below the lower substrate; a first semiconductor chip disposed on the lower substrate and electrically connected to the lower interconnection layer; first intermediate connection structures disposed on one side of the first semiconductor chip on the lower substrate and configured to provide a transmission path for a first signal; second intermediate connection structures disposed on the other side, opposing the one side of the first semiconductor chip on the lower substrate and configured to provide a transmission path for a second signal different from the first signal; an upper substrate disposed on the first semiconductor chip, the first intermediate connection structures, and the second intermediate connection structures; a third semiconductor chip overlapping the first semiconductor chip on the upper substrate in a perpendicular direction, which is perpendicular to the first semiconductor chip, and electrically connected to the first intermediate connection structures; and a fourth semiconductor chip spaced apart from the third semiconductor chip on the upper substrate in a first direction, intersecting the perpendicular direction, and electrically connected to the second intermediate connection structures, wherein the first intermediate connection structures and the second intermediate connection structures may be spaced apart from each other in the first direction with the first semiconductor chip interposed therebetween.

According to an example embodiment of the present disclosure, a semiconductor package may include: a lower substrate having an upper surface including a first region, a second region, and a third region sequentially arranged in a first direction, and including a lower interconnection layer; a first logic chip disposed on the second region and electrically connected to the lower interconnection layer; a first memory chip spaced apart from the first logic chip in the second region and electrically connected to the first logic chip; intermediate connection structures disposed on the lower substrate and electrically connected to the lower interconnection layer; an upper substrate disposed on the first logic chip and the intermediate connection structures; a second memory chip overlapping the first logic chip on the upper substrate in a direction, perpendicular to the first logic chip; and a second logic chip spaced apart from the second memory chip on the upper substrate in the first direction, and electrically connected to the second memory chip, wherein the intermediate connection structures may include first intermediate connection structures disposed on the third region and electrically connected to the second logic chip, and second intermediate connection structures spaced apart from the first intermediate connection structures on the first region in the first direction and electrically connected to the second memory chip.

The semiconductor package according to example embodiments of the present disclosure may include a lower substrate and semiconductor chips provided on an upper substrate on the lower substrate, and connection structures disposed on an upper surface and a lower surface of the lower substrate and providing electrical paths for the semiconductor chips, so that connection structures connected to a ground signal may be minimized, and a signal transmission path may be shortened, thereby providing a semiconductor package having improved integration and electrical characteristics.

Advantages and effects of the present application are not limited to the foregoing content and may be variously extended without departing from the spirit and scope of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view of a semiconductor package according to example embodiments of the present disclosure;

FIG. 2A is a cross-sectional view illustrating an example embodiment taken along line I-I′ of FIG. 1;

FIG. 2B is a cross-sectional view illustrating an example embodiment taken along the line II-II′ of FIG. 1;

FIG. 3 is a plan view illustrating an array of the third connection pattern and the fourth connection pattern of FIG. 1;

FIG. 4A is a plan view illustrating an example embodiment of the intermediate connection structures of FIG. 2A;

FIG. 4B is a plan view illustrating another example embodiment of the intermediate connection structures of FIG. 2A;

FIG. 4C is a plan view illustrating another example embodiment of the intermediate connection structures of FIG. 2A;

FIG. 5 is a plan view illustrating an example embodiment of the lower connection structures of FIG. 2A;

FIG. 6 is a plan view of a semiconductor package according to another example embodiment of the present disclosure;

FIG. 7 is a cross-sectional view illustrating an example embodiment taken along line III-III′ of FIG. 6;

FIG. 8A is a plan view illustrating an example embodiment an array of the intermediate connection structures of FIG. 7;

FIG. 8B is a plan view illustrating another example embodiment of an array of the intermediate connection structures of FIG. 7;

FIG. 9 is a plan view illustrating an example embodiment of an array of the lower connection structure of FIG. 8A; and

FIGS. 10 to 15 are views illustrating an example embodiment of a method of manufacturing the semiconductor package of FIG. 1.

### DETAILED DESCRIPTION

Hereinafter, example embodiments of the present disclosure will be described with reference to the accompanying drawings. The same reference numerals are used for the same components in the drawings, and duplicate descriptions for the same components are omitted.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

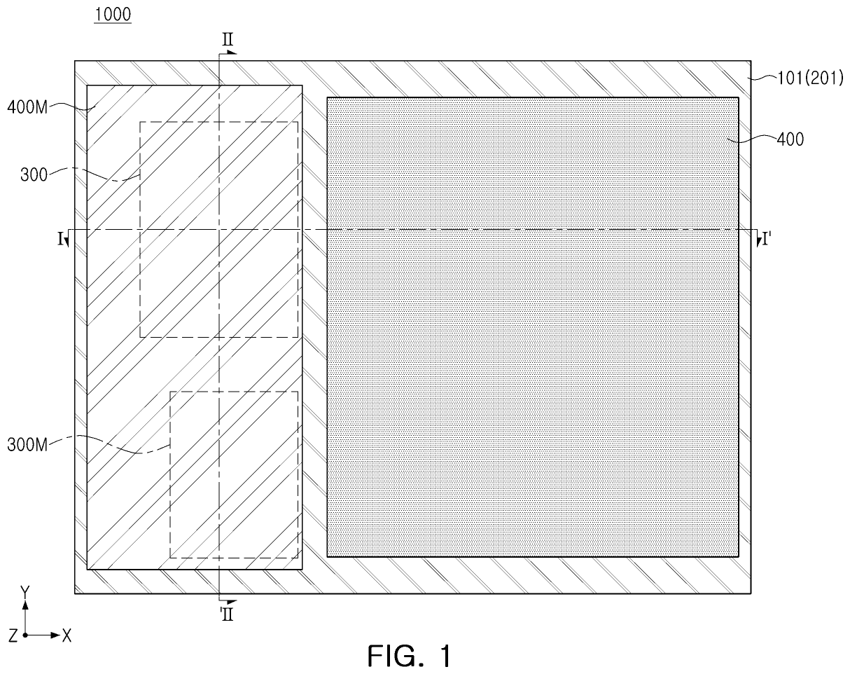

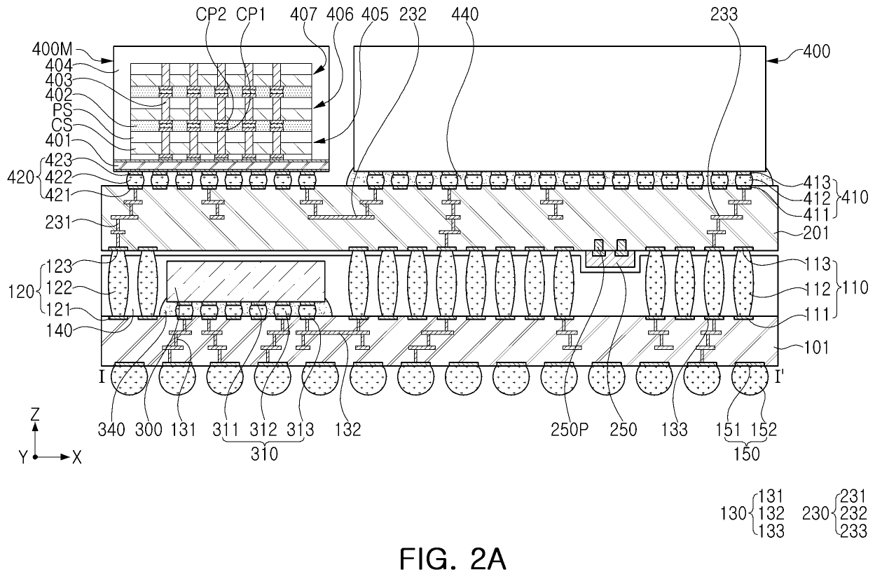

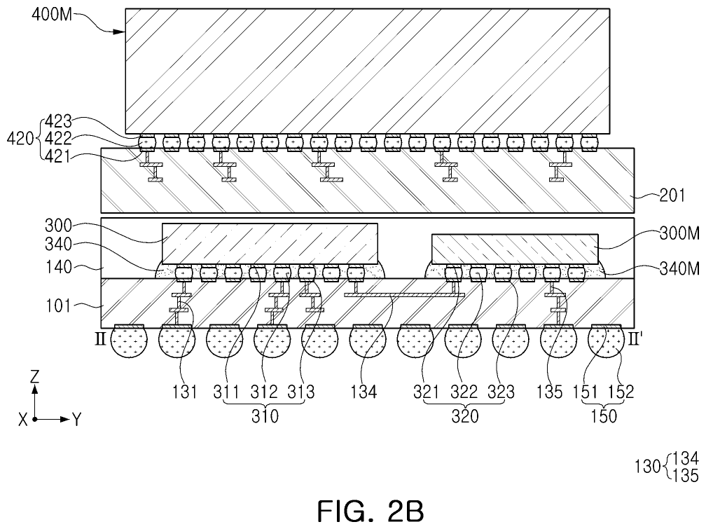

FIG. 1 is a plan view of a semiconductor package according to example embodiments of the present disclosure. FIG. 2A is a cross-sectional view illustrating an example embodiment taken along line I-I′ of FIG. 1. FIG. 2B is a cross-sectional view illustrating an example embodiment taken along the line II-II′ of FIG. 1.

Referring to FIGS. 1, 2A and 2B, a semiconductor package 1000 may include a lower substrate 101, lower connection structures 150 disposed on a lower surface of the lower substrate 101, first and second semiconductor chips 300 and 300M disposed on an upper surface of the lower substrate 101, intermediate connection structures 110 and 120 disposed on an upper surface of the lower substrate 101, an upper substrate 201 disposed on the first and second semiconductor chips 300 and 300M and the intermediate connection structures 110 and 120, and third and fourth semiconductor chips 400 and 400M on an upper surface of the upper substrate 201.

The lower substrate 101 may be a support substrate on which the first and second semiconductor chips 300 and 300M are mounted, and may be a substrate for a semiconductor package including a printed circuit board (PCB), a ceramic substrate, a glass substrate, and/or a tape interconnection substrate. In one example, the lower substrate 101 may include different materials depending on the type of substrate. For example, when the lower substrate 101 is a printed circuit board, the lower substrate 101 may be in the form in which an interconnection layer is additionally stacked on one or both sides of a copper clad laminate. In one example, a solder resist layer may be disposed on a lower surface and an upper surface of the lower substrate 101.

The lower substrate 101 may include a lower surface on which the lower connection structures 150 are disposed and an upper surface on which the first and second semiconductor chips 300 and 300M and the intermediate connection structures 110 and 120 are disposed.

The lower substrate 101 may include a lower interconnection layer 130. The lower interconnection layer 130 may provide different connection signal patterns. In one example, the lower interconnection layer 130 may include a first lower signal pattern 131 electrically connecting the first semiconductor chip 300 and the lower connection structure 150, a second lower signal pattern 132 electrically connecting the first semiconductor chip 300 and the first intermediate connection structures 110, a third lower signal pattern 133 electrically connecting the first intermediate connection structures 110 and the lower connection structures 150, a fourth lower signal pattern 134 electrically connecting the first and second semiconductor chips 300 and 300M to each other, and a fifth lower signal pattern 135 electrically connecting the second semiconductor chip 300M and the lower connection structures 150. Each of the first lower signal pattern 131, the second lower signal pattern 132, the third lower signal pattern 133, the fourth lower signal pattern 134, and the fifth lower signal pattern 135 may be comprised of lines and vias that extend through the lower substrate 101, and each of the lines and vias of the first lower signal pattern 131, the second lower signal pattern 132, the third lower signal pattern 133, the fourth lower signal pattern 134, and the fifth lower signal pattern 135 may be comprised of a conductive material.

The lower connection structures 150 may be disposed on the lower surface of the lower substrate 101. The lower connection structures 150 may be arranged in a grid pattern on the lower surface of the lower substrate 101. In one example, each of the lower connection structures 150 may include lower connection pads 151 and lower connection bumps 152 connected to the lower connection pads 151. The lower connection pads 151 may include metal pads to be electrically connected to the lower interconnection layer 130. In example embodiments, lower surfaces of the lower connection pads 151 may be coplanar with a lower surface of the lower substrate 101, and each of the lower connection bumps 152 may contact a corresponding one of the lower connection pads 151. For example, the lower connection pads 151 may include aluminum (Al), gold (Au), silver (Ag), nickel (Ni), or palladium (Pd). The lower connection bumps 152 may include a plurality of solder balls. The present disclosure is not limited thereto. For example, the lower connection bumps 152 may include at least one of a conductive bump, a conductive spacer, and a ball grid array (BGA). The lower connection bumps 152 may include tin (Sn) or an alloy including tin (Sn) (e.g., Sn—Ag—Cu). The lower connection bumps 152 may be used to electrically connect to external devices such as a module substrate or a system board.

The lower connection structure 150 may be disposed on a main board (not illustrated) disposed below the semiconductor package 1000. The main board may be a printed circuit board (PCB), a ceramic interconnection structure, a glass interconnection board, an interposer interconnection board, and the like. However, example embodiments according to the technical concept of the present disclosure are not limited thereto.

A first semiconductor chip 300 may be disposed on the lower substrate 101. The first semiconductor chip 300 may be mounted on the lower substrate 101 using a flip-chip method. In one example, the first semiconductor chip 300 may be mounted on the lower substrate 101 through first connection patterns 310. Each first connection pattern 310 may include a first upper pad 311 disposed on a lower surface of the first semiconductor chip 300, a first lower pad 313 disposed on the upper surface of the lower substrate 101, and a first connection bump 312 disposed between the first upper pad 311 and the first lower pad 313. For example, the first upper pad 311 may contact the lower surface of the first semiconductor chip 300, an upper surface of the first lower pad 313 may be coplanar with an upper surface of the lower substrate 101, and the first connection bump 312 may contact each of the first upper pad 311 and the first lower pad 313. The first upper pad 311 and the first lower pad 313 may include a conductive material. The first connection bump 312 may include a plurality of solder balls. However, the present disclosure is not limited thereto, and the first connection bump 312 may include at least one of a land, a ball, and/or a pin.

The first connection pattern 310 may electrically connect the first semiconductor chip 300 and the lower interconnection layer 130 of the lower substrate 101.

The first semiconductor chip 300 may include a communication processor (CP). However, the present disclosure is not limited thereto. The first semiconductor chip 300 may include a logic chip such as a modem, a central processing unit (CPU), or a graphic processing unit (GPU). In this document, the first semiconductor chip 300 may be referred to as a first logic chip.

The semiconductor package 1000 may further include a first underfill 340 provided between the first semiconductor chip 300 and the lower substrate 101. In one example, the first underfill 340 may fill a side space of the first connection pattern 310 between the first semiconductor chip 300 and the lower substrate 101. For example, the first underfill 340 may contact a lower surface of the first semiconductor chip 300, an upper surface of the lower substrate 101, and side surfaces of the first upper pads 311 and the first connection bumps 312. The first underfill 340 may be disposed and/or formed by a capillary underfill (CUF) process, but the present disclosure is not limited thereto. The first underfill 340 may include an insulating resin. For example, the first underfill 340 may include a thermosetting resin, a thermoplastic resin such as polyimide, or a prepreg including an inorganic filler or/and glass fiber, ABF (ajinomoto build-up film), FR-4, BT (bismaleimide triazine), and EMC (epoxy molding compound).

The second semiconductor chip 300M may be disposed on the upper surface of the lower substrate 101. The second semiconductor chip 300M may be spaced apart from the first semiconductor chip 300 in a horizontal direction. In one example, the second semiconductor chip 300M may be spaced apart from the first semiconductor chip 300 in a second direction (Y-direction). The second semiconductor chip 300M may be mounted on the lower substrate 101 using a flip-chip method. The second semiconductor chip 300M may be mounted on the lower substrate 101 through the second connection patterns 320. Each second connection pattern 320 may include a second upper pad 321 disposed on the lower surface of the second semiconductor chip 300M, a second lower pad 323 disposed on the upper surface of the lower substrate 101, and a second connection bump 322 disposed between the second lower pad 323 and the second upper pad 321. The second upper pad 321 may contact the lower surface of the second semiconductor chip 300M, an upper surface of the second lower pad 323 may be coplanar with an upper surface of the lower substrate 101, and the second connection bump 322 may contact each of the second upper pad 321 and the second lower pad 323. In one example, the second lower pad 323 and the second upper pad 321 may include the same material as the first lower pad 313 and the first upper pad 311. However, the present disclosure is not limited thereto. The second lower pad 323 and the second upper pad 321 may include a conductive material different from that of the first lower pad 313 and the first upper pad 311. In one example, the second connection bump 322 may include the same conductive material as the first connection bump 312. However, the present disclosure is not limited thereto, and the second connection bump 322 may include a conductive material different from that of the first connection bump 312.

The second connection pattern 320 may electrically connect the second semiconductor chip 300M and the lower interconnection layer 130 of the lower substrate 101.

The second semiconductor chip 300M may be electrically connected to the first semiconductor chip 300 through the second connection pattern 320 and the lower interconnection layer 130.

The second semiconductor chip 300M may include a volatile memory chip such as a Dynamic Random Access Memory (DRAM) or a Static Random Access Memory (SRAM), or a non-volatile memory chip such as a Phase-change Random Access Memory (PRAM), a Magnetoresistive Random Access Memory (MRAM), a Ferroelectric Random Access Memory (FeRAM) or a Resistive Random Access Memory (RRAM). In this document, the second semiconductor chip 300M may be referred to as a first memory chip.

The semiconductor package 1000 may further include a second underfill 340M provided between the second semiconductor chip 300M and the lower substrate 101. In one example, the second underfill 340M may fill a side space of the second connection pattern 320 between the second semiconductor chip 300M and the lower substrate 101. For example, the second underfill 340M may contact a lower surface of the second semiconductor chip 300M, an upper surface of the lower substrate 101, and side surfaces of the second upper pads 321 and the second connection bumps 322. The second underfill 340M may include the same material as the first underfill 340, and the second underfill 340M may be formed in the same process as the first underfill 340. However, the present disclosure is not limited thereto, and the second underfill 340M may include a different material from the first underfill 340 and may be formed through a process different from the first underfill 340.

When viewed in plan view, an area of the second semiconductor chip 300M may be smaller than an area of the first semiconductor chip 300. In one example, a width of the second semiconductor chip 300M in the first direction (X-direction) may be narrower than a width of the first semiconductor chip 300 in the first direction (X-direction), and a width of the second semiconductor chip 300M in a second direction (Y-direction) may be narrower than a width of the first semiconductor chip 300 in the first direction (X-direction). In another example, when viewed in plan view, an area of the second semiconductor chip 300M may be larger than an area of the first semiconductor chip 300.

A height of the second semiconductor chip 300M in a vertical direction (Z-direction) may be smaller than a height of the first semiconductor chip 300 in the vertical direction (Z-direction). For example, a distance between a lower surface and an upper surface of the second semiconductor chip 300M may be smaller than a distance between a lower surface and an upper surface of the first semiconductor chip 300. In an example embodiment, the upper surface of the first semiconductor chip 300 may be at a higher vertical level than the upper surface of the second semiconductor chip 300M. However, the present disclosure is not limited thereto, and the height of the second semiconductor chip 300M in the vertical direction (Z-direction) may be greater than a height of the first semiconductor chip 300. For example, a distance between a lower surface and an upper surface of the first semiconductor chip 300 may be smaller than a distance between a lower surface and an upper surface of the second semiconductor chip 300M. In an example embodiment, the upper surface of the second semiconductor chip 300M may be at a higher vertical level than the upper surface of the first semiconductor chip 300.

The intermediate connection structures 110 and 120 may be disposed on the upper surface of the lower substrate 101. The intermediate connection structures 110 and 120 may include first intermediate connection structures 110 and second intermediate connection structures 120 spaced apart from each other in the first direction (X-direction) with the first semiconductor chip 300 and the second semiconductor chip 300M interposed therebetween.

In one example, the first intermediate connection structures 110 may be arranged in a grid pattern on one side of the first semiconductor chip 300. The second intermediate connection structures 120 may be arranged in a grid pattern on the other side opposing the one side of the first semiconductor chip 300.

The first intermediate connection structures 110 and the second intermediate connection structures 120 may provide a transmission path of signals for the third semiconductor chip 400M and the fourth semiconductor chip 400, and the signals may include a power signal, a data signal, a command signal, and an address signal.

A first signal may be transmitted to the fourth semiconductor chip 400 through the first intermediate connection structures 110. A second signal different from the first signal may be transmitted to the third semiconductor chip 400M through the second intermediate connection structures 120. The first signal may include a power signal, a data signal, and/or an address signal for the fourth semiconductor chip 400. The second signal may include a power signal for the third semiconductor chip 400M.

Each of the first intermediate connection structures 110 may include a first intermediate lower pad 111, a first intermediate upper pad 113, and a first intermediate bump 112 disposed between the first intermediate lower pad 111 and the first intermediate upper pad 113. The first intermediate lower pad 111 may be disposed on the upper surface of the lower substrate 101, the first intermediate upper pad 113 may be disposed on a lower surface of the upper substrate 201, and the first intermediate bump 112 may be disposed between the first intermediate lower pad 111 and the first intermediate upper pad 113 to electrically connect the first intermediate lower pad 111 and the first intermediate upper pad 113. For example, a lower surface of the first intermediate upper pad 113 may be coplanar with the lower surface of the upper substrate 201, an upper surface of the first intermediate lower pad 111 may be coplanar with an upper surface of the upper substrate 201, and the first intermediate bump 112 may contact each of the first intermediate upper pad 113 and the first intermediate lower pad 111.

Each of the second intermediate connection structures 120 may include a second intermediate lower pad 121, a second intermediate upper pad 123, and a second intermediate bump 122 disposed between the second intermediate lower pad 121 and the second intermediate upper pad 123. The second intermediate lower pad 121 may be disposed on the upper surface of the lower substrate 101, the second intermediate upper pad 123 may be disposed on the lower surface of the upper substrate 201, and the second intermediate bump 122 may be disposed between the second intermediate lower pad 121 and the second intermediate upper pad 123 to electrically connect the second intermediate lower pad 121 and the second intermediate upper pad 123. For example, a lower surface of the second intermediate upper pad 123 may be coplanar with the lower surface of the upper substrate 201, an upper surface of the second intermediate lower pad 121 may be coplanar with an upper surface of the upper substrate 201, and the second intermediate bump 122 may contact each of the second intermediate upper pad 123 and the second intermediate lower pad 121.

The first intermediate bump 112 and the second intermediate bump 122 may have a bump or pillar shape. The first and second intermediate bumps 112 and 122 may include a solder material and/or a metal pillar. For example, the first and second intermediate bumps 112 and 122 may include at least one of copper (Cu) and a copper (Cu) alloy.

The first intermediate lower pad 111, the first intermediate upper pad 113, the second intermediate lower pad 121 and second intermediate upper pad 123 may include metal pads. For example, the first intermediate lower pad 111, the first intermediate upper pad 113, the second intermediate lower pad 121 and second intermediate upper pad 123 may be formed of or include aluminum (Al), gold (Au), silver (Ag), nickel (Ni), or palladium (Pd).

The semiconductor package 1000 may further include a mold layer 140 configured to cover the first and second semiconductor chips 300 and 300M and to cover at least a portion of side surfaces of the intermediate connection structures 110 and 120. The mold layer 140 may cover side surfaces and upper surfaces of the first and second semiconductor chips 300 and 300M, and may cover at least a portion of side surfaces of the first and second intermediate bumps 112 and 122. For example, the mold layer 140 may contact side and upper surfaces of the first and second semiconductor chips 300 and 300M, and may contact at least a portion of the side surfaces of the first and second intermediate bumps 112 and 122. In one example, the mold layer 140 may covers only a portion of the first and second intermediate bumps 112 and 122, thereby exposing at least a portion of the first and second intermediate bumps 112 and 122 adjacent to the first and second intermediate upper pads 113 and 123. However, the present disclosure is not limited thereto, and the mold layer 140 may completely cover the side surfaces of the intermediate connection structures 110 and 120.

The mold layer 140 may be formed in a molded underfill (MUF) process. The mold layer 140 may include an epoxy molding compound (EMC). However, the present disclosure is not limited thereto, and the mold layer 140 may include various materials such as an epoxy-based material, a thermosetting material, a thermoplastic material, and a UV-treated material.

The upper substrate 201 may be disposed on the intermediate connection structures 110 and 120. The upper substrate 201 is a support substrate on which the third semiconductor chip 400M and the fourth semiconductor chip 400 are mounted, and may be a substrate for a semiconductor package including a printed circuit board (PCB), a ceramic substrate, a glass substrate, and a tape interconnection substrate.

The upper substrate 201 may include a lower surface in which the first and second intermediate upper pads 113 and 123 and passive elements 250P and 250 are disposed, and an upper surface on which the third and fourth semiconductor chips 400M and 400 are disposed.

The lower substrate 101 and the upper substrate 201 may have substantially the same area when viewed in plan view. However, the present disclosure is not limited thereto, and when viewed in plan view, an area of the lower substrate 101 may be larger or smaller than an area of the upper substrate 201.

A height of the lower substrate 101 in the vertical direction (Z-direction) may be smaller than a height of the upper substrate 201 in the vertical direction (Z-direction). For example, a distance between the lower and upper surfaces of the lower substrate 101 may be smaller than a distance between the lower and upper surfaces of the upper substrate 201.

The upper substrate 201 may include an upper interconnection layer 230. The upper interconnection layers 230 may provide different connection signal patterns. In one example, the upper interconnection layers 230 may include a first upper signal pattern 231 electrically connecting the third semiconductor chip 400M and the second intermediate connection structures 120, a second upper signal pattern 232 electrically connecting the third and fourth semiconductor chips 400M and 400, and a third upper signal pattern 233 electrically connecting the fourth semiconductor chip 400 and the first intermediate connection structures 110. Each of the first upper signal pattern 231, the second upper signal pattern 232, and the third upper signal pattern 233 may be comprised of lines and vias that extend through the upper substrate 201, and each of the lines and vias of the first upper signal pattern 231, the second upper signal pattern 232, and the third upper signal pattern 233 may be comprised of a conductive material.

The first semiconductor chip 300 may be electrically connected to the fourth semiconductor chip 400 through the second lower signal pattern 132, the first intermediate connection structures 110 and the third upper signal pattern 233. The second lower signal pattern 132, the first intermediate connection structures 110 and the third upper signal pattern 233 may be included in a Universal Chiplet Interconnect Express (UCIe) interface.

The third semiconductor chip 400M and the fourth semiconductor chip 400 may be disposed on the upper surface of the upper substrate 201.

The third semiconductor chip 400M may overlap the first semiconductor chip 300 and the second semiconductor chip 300M in the vertical direction (Z-direction). In another example, the third semiconductor chip 400M may overlap the first semiconductor chip 300 in the vertical direction (Z-direction) and may overlap a portion of the second semiconductor chip 300M.

The third semiconductor chip 400M may be mounted on the upper substrate 201 using a flip-chip method. In one example, the third semiconductor chip 400M may be mounted on the upper substrate 201 through third connection patterns 420. Each third connection pattern 420 may include a third upper pad 423 disposed on a lower surface of the third semiconductor chip 400M, a third lower pad 421 disposed on the upper surface of the upper substrate 201, and a third connection bump 422 disposed between the third upper pad 423 and the third lower pad 421. For example, the third upper pad 423 may contact the lower surface of the third semiconductor chip 400M, an upper surface of the third lower pad 421 may be coplanar with an upper surface of the upper substrate 201, and the third connection bump 422 may contact each of the third upper pad 423 and the third lower pad 421. The third upper pad 423 and third lower pad 421 may include a conductive material. The third connection bump 422 may include a plurality of solder balls.

The third connection patterns 420 may be an electrical path connecting the third semiconductor chip 400M and the upper interconnection layer 230.

The third semiconductor chip 400M may be a memory chip. The memory chip may include a volatile memory chip such as a Dynamic Random Access Memory (DRAM) or a Static Random Access Memory (SRAM), or a non-volatile memory chip such as a Phase-change Random Access Memory (PRAM), a Magnetoresistive Random Access Memory (MRAM), a Ferroelectric Random Access Memory (FeRAM), or a Resistive Random Access Memory (RRAM). In this document, the third semiconductor chip 400M may be referred to as a second memory chip.

The third semiconductor chip 400M may overlap the second intermediate connection structures 120 in the vertical direction (Z-direction). The third semiconductor chip 400M may be electrically connected to the first upper signal pattern 231 and the second intermediate connection structure 120 through the third connection patterns 420. A power signal may be applied to the third semiconductor chip 400M through the first upper signal pattern 231 and the second intermediate connection structure 120.

The third semiconductor chip 400M may include a base substrate 401, a plurality of semiconductor chips 405, 406, and 407, an adhesive material layer 402, and a mold layer 404.

The base substrate 401 may include a buffer semiconductor chip or a logic semiconductor chip. In one example, the base substrate 401 may have a width or a size larger than the plurality of semiconductor chips 405, 406, and 407. The third connection patterns 420 may be disposed on a lower surface of the base substrate 401.

The plurality of semiconductor chips 405, 406, and 407 may be sequentially stacked in the vertical direction (Z-direction) on the base substrate 401. In one example, the first semiconductor chip 405 may be disposed on the base substrate 401, the second semiconductor chip 406 may be disposed on the first semiconductor chip 405, and the third semiconductor chip 407 may be disposed on the second semiconductor chip 406. The plurality of semiconductor chips 405, 406, and 407 are illustrated as including three semiconductor chips, but the present disclosure is not limited thereto. For example, the plurality of semiconductor chips 405, 406 and 407 may include four or more semiconductor chips.

The plurality of semiconductor chips 405, 406, and 407 are illustrated as having the same shape, but the present disclosure is not limited thereto. For example, the plurality of semiconductor chips 405, 406, and 407 may include different types of semiconductor chips or semiconductor chips of different shapes. In one example, the plurality of semiconductor chips 405, 406, and 407 may be memory semiconductor chips such as a DRAM. Each of the plurality of semiconductor chips 405, 406, and 407 may a first chip structure CS, a second chip structure PS disposed on the first chip structure CS, and a connection structure 403 penetrating through the first chip structure CS and the second chip structure PS. In one example, the first chip structure CS may include a memory structure and a cell routing interconnection structure electrically connected to the memory structure. In one example, the second chip structure PS may be stacked in the vertical direction (Z-direction) of the first chip structure CS. The second chip structure PS may include peripheral circuits and peripheral routing interconnection structures electrically connected to the peripheral circuits.

The plurality of semiconductor chips 405, 406, and 407 may be electrically connected to each other through the first and second connection pads CP1 and CP2. The first connection pad CP1 may be disposed on a lower surface of the first chip structure CS, and the second connection pad CP2 may be disposed on an upper surface of the second chip structure PS.

The first and second connection pads CP1 and CP2 of one of the plurality of semiconductor chips 405, 406, and 407 may electrically connect the one semiconductor chip and the semiconductor chip adjacent to the one semiconductor chip. For example, the first connection pad CP1 of the first semiconductor chip 405 may electrically connect the first semiconductor chip 405 and the base substrate 401. The second connection pad CP2 of the first semiconductor chip 405 may be connected to the first connection pad CP1 of the second semiconductor chip 406 to electrically connect the first semiconductor chip 405 and the second semiconductor chip 406.

The connection structure 403 may be disposed between the first and second connection pads CP1 and CP2 to electrically connect the first and second connection pads CP1 and CP2. The connection structure 403 may be formed in various shapes and/or structures.

The adhesive material layer 402 may surround a space between the first semiconductor chip 405 and the base substrate 401, a space between the plurality of semiconductor chips 405, 406, and 407 and side surfaces of the plurality of semiconductor chips 405, 406, and 407. In one example, the adhesive material layer 402 may be formed of or include an epoxy material. For example, the adhesive material layer 402 may be a non-conductive film (NCF), and the example embodiment of the present disclosure is not limited to the material.

The mold layer 404 may protect the plurality of semiconductor chips 405, 406, and 407 and the adhesive material layer 402 from the external environments so as to cover the plurality of semiconductor chips 405, 406, and 407 and the adhesive material layer 402. In one example, the mold layer 404 may include an insulating material including a resin material, such as an epoxy molding compound (EMC).

The fourth semiconductor chip 400 may be spaced apart from the third semiconductor chip 400M on the upper substrate 201 in the first direction (X-direction).

The fourth semiconductor chip 400 may be mounted on the upper substrate 201 using a flip-chip method. In one example, the fourth semiconductor chip 400 may be mounted on the upper substrate 201 through the fourth connection patterns 410. Each fourth connection pattern 410 may include a fourth upper pad 413 disposed on a lower surface of the fourth semiconductor chip 400, a fourth lower pad 411 disposed on the upper surface of the upper substrate 201, and a fourth connection bump 412 disposed between the fourth upper pad 413 and the fourth lower pad 411. For example, the fourth upper pad 413 may contact the lower surface of the fourth semiconductor chip 400, an upper surface of the fourth lower pad 411 may be coplanar with an upper surface of the upper substrate 201, and the fourth connection bump 412 may contact each of the fourth upper pad 413 and the fourth lower pad 411.

The fourth semiconductor chip 400 may include a logic chip, a processor chip, or a controller chip. In one example, the fourth semiconductor chip 400 may include an application processor (AP), a mobile AP, a chip set, or a set of chips. The fourth semiconductor chip 400 may be a semiconductor chip performing a different function from the first semiconductor chip 300. In this document, the fourth semiconductor chip 400 may be referred to as a second logic chip.

The semiconductor package 1000 may further include capacitors 250 and 250P disposed on the lower surface of the upper substrate 201.

The capacitors 250 and 250P may include a connection portion 250P disposed below the upper substrate 201 and a main body portion 250 electrically connected to the upper interconnection layer 230 of the upper substrate 201 through the connection portion 250P.

The capacitors 250 and 250P may be surrounded by the first intermediate connection structures 110. The capacitors 250 and 250P may be disposed on the lower surface of the upper substrate 201 as a space between the lower interconnection layer 130 and the upper interconnection layer 230, thus minimizing an electrical connection path.

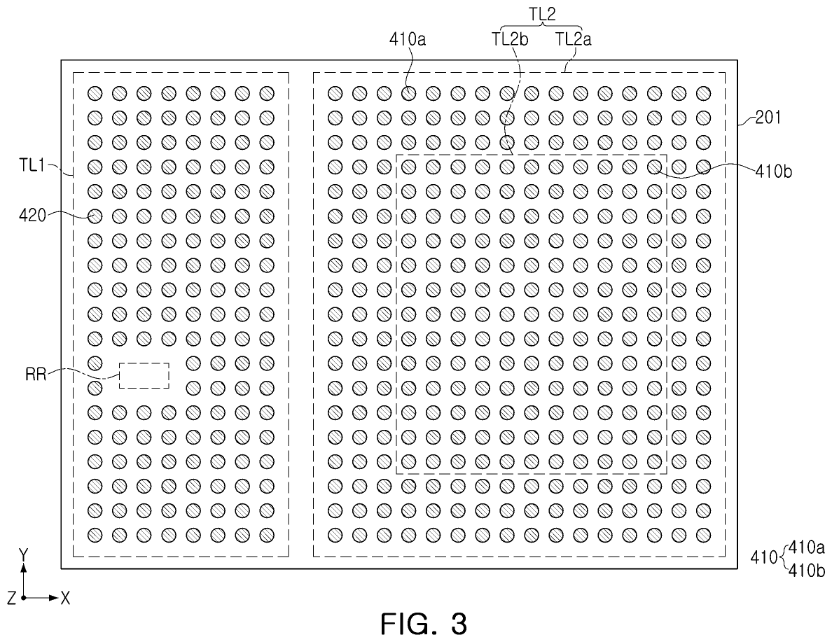

FIG. 3 is a plan view illustrating an array of the third connection pattern and the fourth connection pattern of FIG. 1.

Referring to FIG. 3, an array of the third connection patterns 420 disposed on the lower surface of the third semiconductor chip 400M and an array of the fourth connection patterns 410 disposed on the lower surface of the fourth semiconductor chip 400 are illustrated.

The upper surface of the upper substrate 201 may include a first upper region TL1 and a second upper region TL2. The first upper region TL1 is a region in which the third semiconductor chip 400M and the upper substrate 201 overlap each other in the vertical direction, and may be a region in which the third connection patterns 420 are disposed. In one example, the second upper region TL2 is a region in which the fourth semiconductor chip 400 and the upper substrate 201 overlap each other in the vertical direction (Z-direction), and may be a region in which the fourth connection patterns 410 are disposed. The first upper region TL1 and the second upper region TL2 may be spaced apart from each other in the first direction (X-direction).

When viewed in plan view, an area of the second upper region TL2 may be larger than an area of the first upper region TL1.

The third connection patterns 420 may form a regular array by forming a plurality of rows and columns inside the first upper region TL1. The first upper region TL1 may include a routing pad region RR. The third connection patterns 420 are not disposed in the routing pad region RR, and a routing interconnection structure (not illustrated) of the third semiconductor chip 400M may be disposed.

The third semiconductor chip 400M may be electrically connected to the first upper signal pattern 231 of the upper substrate 201 through the third connection patterns 420. In one example, the third connection patterns 420 may provide a transmission path for a power signal of the third semiconductor chip 400M.

The fourth connection patterns 410 may form a regular array by forming a plurality of rows and columns inside the second upper region TL2. The second upper region TL2 may include a 2-1 upper region TL2a and a 2-2 upper region TL2b surrounded by the 2-1 upper region TL2a. The fourth connection patterns 410 may include 4-1 connection patterns 410a disposed in the 2-1 upper region TL2a and 4-2 connection patterns 410b disposed in the 2-2 upper region TL2b.

The 4-1 connection patterns 410a may provide a transmission path for a power signal of the fourth semiconductor chip 400. The 4-2 connection patterns 410b may provide a transmission path for a data signal and/or an address signal of the fourth semiconductor chip 400.

The third connection patterns 420 may be arranged in a 19×8 matrix. However, the present disclosure is not limited thereto, and a plurality of rows and columns of the third connection patterns 420 may be determined according to a size of the third connection patterns 420 and an area of the lower surface of the third semiconductor chip 400M on a plane.

The fourth connection patterns 410 may be arranged in a 19×16 matrix. However, the present disclosure is not limited thereto, and a plurality of rows and columns of the fourth connection patterns 410 may be determined depending on a size of the fourth connection patterns 410 and an area of the lower surface of the fourth semiconductor chip 400 on a plane.

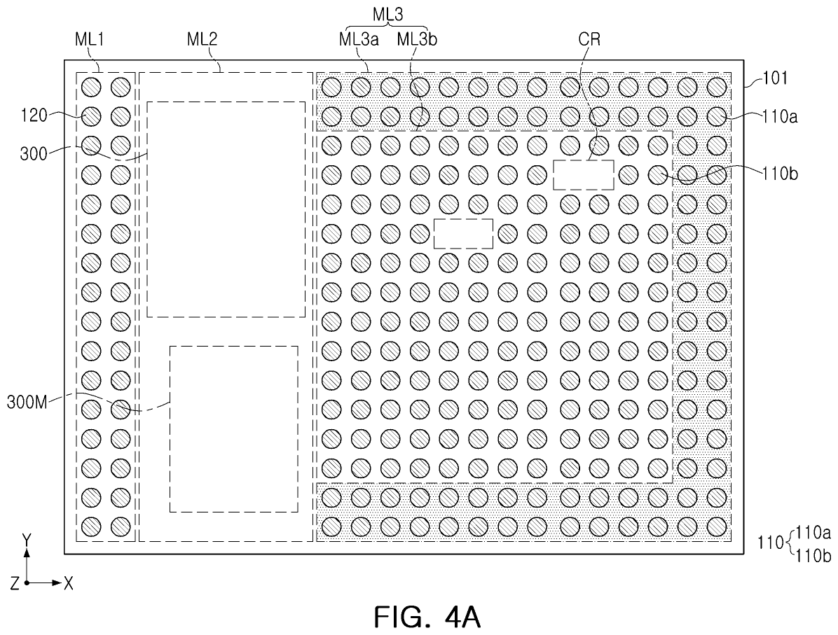

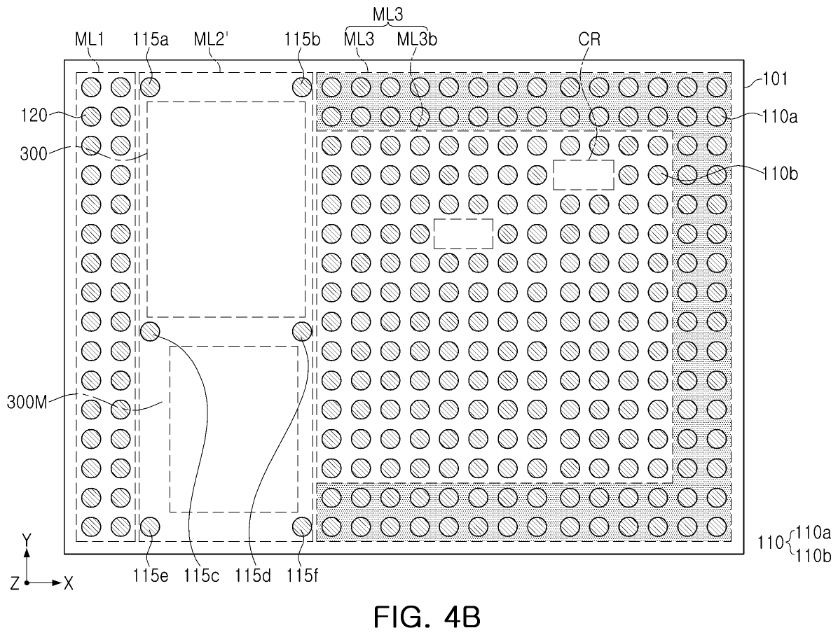

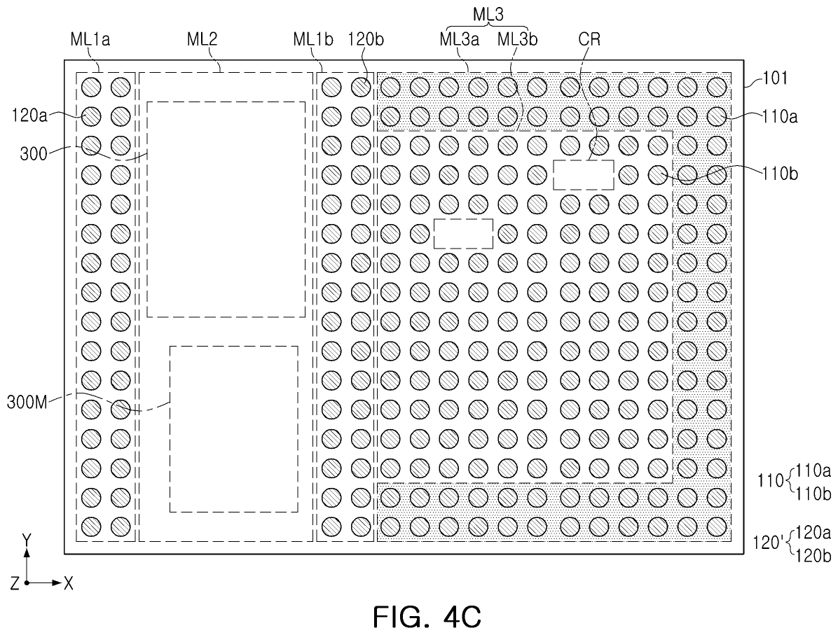

FIG. 4A is a plan view illustrating an example embodiment of the intermediate connection structures of FIG. 2A.

Referring to FIGS. 2A and 4A, the upper surface of the lower substrate 101 may include a first intermediate region ML1, a second intermediate region ML2, and a third intermediate region ML3 sequentially arranged in the first direction (X-direction).

An area of the first intermediate region ML1 may be smaller than an area of the second intermediate region ML2 and an area of the third intermediate region ML3. The area of the third intermediate region ML3 may be larger than the area of the second intermediate region ML2.

The first intermediate region ML1 and the second intermediate region ML2 may overlap the third semiconductor chip 400M in the vertical direction (Z-direction).

The third intermediate region ML3 may overlap the fourth semiconductor chip 400 in the vertical direction (Z-direction).

The first intermediate region ML1 may be a region in which the second intermediate connection structures 120 are disposed. The second intermediate region ML2 may be a region in which the first semiconductor chip 300 and the second semiconductor chip 300M are disposed. The third intermediate region ML3 may be a region where the first intermediate connection structures 110 are disposed.

The intermediate connection structures 110 and 120 may be arranged in a grid pattern.

The second intermediate connection structures 120 disposed on the first intermediate region ML1 and the first intermediate connection structures 110 disposed on the third intermediate region ML3 may be structures supporting the upper substrate 201 so that the upper substrate 201 may be disposed on the lower substrate 101.

Support structures such as the intermediate connection structures 110 and the 120 may not be arranged between the second intermediate region ML2 of the lower substrate 101 and the upper substrate 201 overlapping the second intermediate region ML2 in the vertical direction (Z-direction).

The first intermediate connection structures 110 and the second intermediate connection structures 120 may be spaced apart from each other in the first direction (X-direction) with the first and second semiconductor chips 300 and 300M interposed therebetween.

The density of the second intermediate connection structures 120 disposed on the first intermediate region ML1 may be substantially the same as the density of the first intermediate connection structures 110 disposed on the third intermediate region ML3. In one example, a gap between the first intermediate connection structures 110 may be substantially the same as a gap between the second intermediate connection structures 120. For example, a distance between adjacent ones of the first intermediate connection structures 110 may be substantially the same as a distance between adjacent ones of the second intermediate connection structures 120.

The third intermediate region ML3 may include a 3-1 intermediate region ML3a and a 3-2 intermediate region ML3b in which at least one side thereof is surrounded by the 3-1 intermediate region ML3a.

The 3-2 intermediate region ML3b may include a first side surface adjacent to the second intermediate region ML2 and extending in the second direction (Y-direction), a second side surface in parallel with the first side surface in the second direction (Y-direction), a third side surface connected to the first side surface and extending in the first direction (X-direction), and a fourth side surface in parallel with the third side surface in the first direction (X-direction).

The 3-1 intermediate region ML3a may surround the second side surface, the third side surface, and the fourth side surface of the 3-2 intermediate region ML3b.

The first intermediate connection structures 110 may include 1-1 intermediate connection structures 110a disposed in the 3-1 intermediate region ML3a, and 1-2 intermediate connection structures 110b disposed in the 3-2 intermediate region ML3b.

The 1-1 intermediate connection structures 110a may provide a transmission path for a power signal (hereinafter referred to as a 1-1 intermediate signal) of the fourth semiconductor chip 400. The 1-2 intermediate connection structure 110b may provide a transmission path for a data signal and/or an address signal (hereinafter referred to as a 1-2 intermediate signal) of the fourth semiconductor chip 400.

A size of a bump (e.g., the first intermediate bump 112) of the 1-1 intermediate connection structure 110a may be larger than a size of a bump of the 1-2 intermediate connection structure 110b. The size of the bump may refer to a cross-sectional area of the bump when viewed in plan view. However, the present disclosure is not limited thereto, and the size of the bump of the 1-1 intermediate connection structure 110a may be substantially the same as the size of the bump of the 1-2 intermediate connection structure 110b.

The second intermediate connection structures 120 may provide a transmission path for a power signal (hereinafter referred to as a second intermediate signal) of the third semiconductor chip 400M.

The number of connection structures included in the first intermediate connection structures 110 may be greater than the number of connection structures included in the second intermediate connection structures 120.

The first intermediate connection structures 110 may form a regular array by forming a plurality of rows and columns on the third intermediate region ML3. For example, the first intermediate connection structure 110 may be arranged in a 16×14 array. However, the present disclosure is not limited thereto, and an array of the first intermediate connection structures 110 is not limited thereto, and the first intermediate connection structures 110 may be formed in various arrays.

The second intermediate connection structures 120 may form a regular array by forming a plurality of rows and columns on the first intermediate region ML1. For example, the second intermediate connection structures 120 may be arranged in a 16×2 array. However, the present disclosure is not limited thereto, and the array of the second intermediate connection structures 120 is not limited thereto, and the second intermediate connection structures 120 may be formed in various arrays.

The 3-1 intermediate region ML3a may include a passive device mounting region CR. The passive device mounting area CR may be a region overlapping a capacitor (e.g., capacitors 250 and 250P in FIG. 2A) in the vertical direction (Z-direction). The 2-1 intermediate connection structures 110b may not be disposed on the passive device mounting region CR.

Referring to FIGS. 3 and 4A, when viewed in plan view, a size of each of the first and second intermediate connection structures 110 and 120 may be larger than a pattern size of each of the third connection patterns 420 and the fourth connection patterns 410.

FIG. 4B is a plan view illustrating another example embodiment of the intermediate connection structures of FIG. 2A.

The remaining components except for third intermediate connection structures 115a to 115f may be identical or substantially the same as the components illustrated in FIG. 4A.

The third intermediate connection structures 115a to 115f may be disposed on the second intermediate region ML2. The third intermediate connection structures 115a to 115f may be disposed on the same level as the first and second intermediate connection structures 110 and 120 on the lower substrate 101, and may be formed in the same process as the first and second intermediate connection structures 110 and 120.

The density of the third intermediate connection structures 115a to 115f on the second intermediate region ML2 may be smaller than the density of the second intermediate connection structures 120 on the first intermediate region ML1 and the density of the first intermediate connection structures 110 on the third intermediate region ML3.

A gap between the third intermediate connection structures 115a to 115f may be greater than a gap between the first intermediate connection structures 110 and a gap between the second intermediate connection structures 120. For example, a distance between adjacent ones of the third intermediate connection structures 115a to 115f may be greater than a distance between adjacent ones of the first intermediate connection structures 110 and a distance between adjacent ones of the second intermediate connection structures 120.

The third intermediate connection structures 115a to 115f disposed in the second intermediate region ML2 are not electrically connected to the first to fourth semiconductor chips 300, 300M, 400M and 400, and may serve as a transmission path for a ground signal. The third intermediate connection structures 115a to 115f may be support structures disposed between the first and second intermediate connection structures 110 and 120 to prevent the second intermediate region ML2 of the upper substrate 201 from being tilted downwardly.

The third intermediate connection structures 115a to 115f may be disposed in a region adjacent to an edge of the second intermediate region ML2.

The 3-1 intermediate connection structure 115a and the 3-5 intermediate connection structure 115e may be disposed in an edge of the lower substrate 101 on the second intermediate region ML2 and in a region adjacent to the first intermediate region ML1.

The 3-2 intermediate connection structure 115b and the 3-6 intermediate connection structure 115f may be disposed in the edge of the lower substrate 101 on the second intermediate region ML2 and in a region adjacent to the third intermediate region ML3. In one example, the 3-3 intermediate connection structure 115c disposed between the 3-1 intermediate connection structure 115a and the 3-5 intermediate connection structure 115e may be disposed on the second intermediate region ML2. The 3-4 intermediate connection structure 115d disposed between the 3-2 intermediate connection structure 115b and the 3-6 intermediate connection structure 115f may be disposed on the second intermediate region ML2.

The 3-1 intermediate connection structure 115a, the 3-3 intermediate connection structure 115c, and the 3-5 intermediate connection structure 115e may be spaced apart from each other in the second direction (Y-direction), and may be spaced apart from each other with the first and second semiconductor chips 300 and 300M interposed therebetween. In example embodiments, the 3-1 intermediate connection structure 115a, the 3-3 intermediate connection structure 115c, and the 3-5 intermediate connection structure 115e may aligned with each other in the second direction (Y-direction).

The 3-2 intermediate connection structure 115b, the 3-4 intermediate connection structure 115d, and the 3-6 intermediate connection structure 115f may be spaced apart from each other in the second direction (Y-direction), and may be spaced apart from each other with the first and second semiconductor chips 300 and 300M interposed therebetween. In example embodiments, the 3-2 intermediate connection structure 115b, the 3-4 intermediate connection structure 115d, and the 3-6 intermediate connection structure 115f may be aligned with each other in the second direction (Y-direction).

When viewed in plan view, a size of each of the third intermediate connection structures 115a to 115f may be substantially the same as a size of each of the first and second intermediate connection structures 110 and 120.

The third intermediate connection structures 115a to 115f may provide a transmission path for a ground signal.

The third intermediate connection structures 115a to 115f are illustrated as including six intermediate connection structures, but the present disclosure is not limited thereto, and the third intermediate connection structures 115a to 115f may include six or more intermediate connecting structures, or may include six or fewer intermediate connecting structures.

The semiconductor package according to example embodiments may include the third intermediate connection structures 115a to 115f on the second intermediate region ML2 having density lower than the density of the first intermediate connection structures 110 on the third intermediate region ML3 and the density of the second intermediate connection structures 120 on the first intermediate region ML1, thereby improving warpage of the semiconductor package.

FIG. 4C is a plan view illustrating another example embodiment of the intermediate connection structures of FIG. 2A.

The remaining components except for a second intermediate connection structure 120′ disposed in a 1-1 intermediate region ML1a and a 1-2 intermediate region ML1b may be identical or substantially the same as the components illustrated in FIG. 2A.

Referring to FIG. 4C, the upper surface of the lower substrate 101 may include a 1-1 intermediate region ML1a, a second intermediate region ML2, a 1-2 intermediate region ML1b, and a third intermediate region ML3, which are sequentially arranged in the first direction (X-direction).

The second intermediate connection structures 120′ may be disposed in the 1-1 intermediate region ML1a and the 1-2 intermediate region ML1b. The first and second semiconductor chips 300 and 300M may be disposed in the second intermediate region ML2. The first intermediate connection structure 110 may be disposed in the third intermediate region ML3.

The second intermediate connection structures 120′ may include 2-1 intermediate connection structures 120a disposed in the 1-1 intermediate region ML1a, and 2-2 intermediate connection structures 120b disposed in the 1-2 intermediate region ML1b. In one example, the 2-1 intermediate connection structures 120a and the 2-2 intermediate connection structures 120b may be spaced apart from each other in the first direction (X-direction) with the first semiconductor chip 300 and the second semiconductor chip 300M interposed therebetween.

The 1-2 intermediate region ML1b may be disposed between the second intermediate region ML2 and the third intermediate region ML3.

The 1-1 intermediate region ML1a, the 1-2 intermediate region ML1b and the second intermediate region ML2 may overlap the third semiconductor chip 400M in the vertical direction (Z-direction). The third intermediate region ML3 may overlap the fourth semiconductor chip 400 in the vertical direction (Z-direction).

The 2-1 intermediate connection structures 120a and the 2-2 intermediate connection structures 120b may provide a transmission path for a power signal of the third semiconductor chip 400M.

In the semiconductor packages according to example embodiments, the 2-1 intermediate connection structures 120a and the 2-2 intermediate connection structures 120b disposed on both sides of the first semiconductor chip 300 may provide a transmission path for the power signal of the third semiconductor chip 400M. Accordingly, since an arrangement area of the third semiconductor chip 400M may be secured, the size and the area of the third semiconductor chip 400M may be designed in various ways.

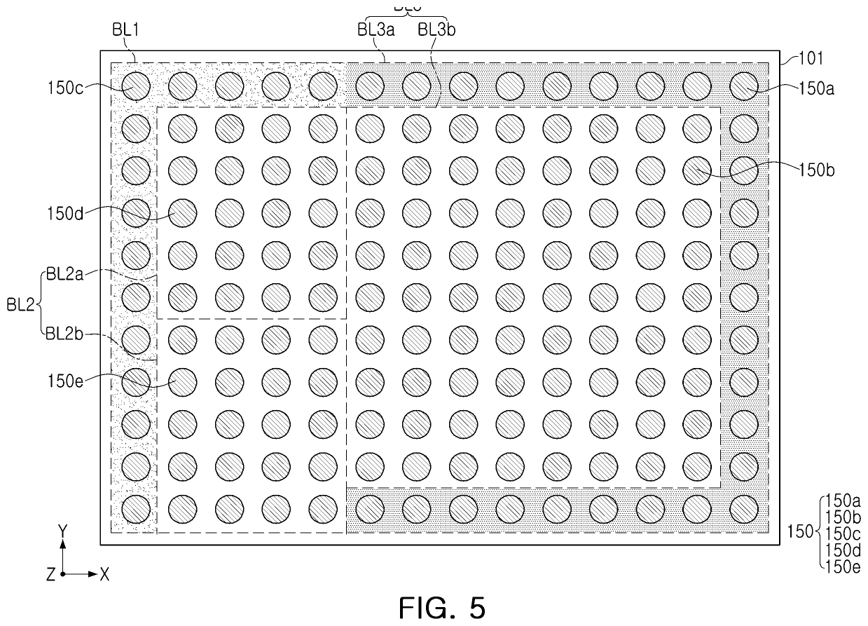

FIG. 5 is a plan view illustrating an example embodiment of the lower connection structures of FIG. 2A.

Referring to FIG. 5, the lower surface of the lower substrate 101 may include a first lower region BL1, a second lower region BL2, and a third lower region BL3, which are sequentially arranged in the first direction (X-direction).

Referring to FIGS. 4A and 5, the first and second lower regions BL1 and BL2 may overlap the first and second intermediate regions ML1 and ML2 in the vertical direction (Z-direction). The third lower region BL3 may overlap the third intermediate region ML3 in the vertical direction (Z-direction).

An area of the first lower region BL1 may be smaller than an area of the second lower region BL2 and an area of the third lower region BL3. The area of the third lower region BL3 may be larger than the area of the second lower region BL2.

Lower connection structures 150 may be disposed in the first, second and third lower regions BL1, BL2, and BL3. The lower connection structures 150 may be arranged in a grid pattern on the lower surface of the lower substrate 101.

The lower connection structure 150 may include first lower connection structures 150a and 150b disposed on the third lower region BL3, and second lower connection structures 150c, 150d, and 150f disposed on the first and second lower regions BL1 and BL2.

The third lower region BL3 may include a 3-1 lower region BL3a and a 3-2 lower region BL3b in which at least one side thereof is surrounded by the 3-1 lower region ML3a.

Referring to FIGS. 4A and 5, the 3-1 lower region BL3a may correspond to the 3-1 intermediate region ML3a. The 3-2 lower region BL3b may correspond to the 3-2 lower region ML3b. In one example, the 3-1 lower region BL3a may overlap the 3-1 intermediate region ML3a in the vertical direction (Z-direction). The 3-2 lower region BL3b may overlap the 3-2 intermediate region ML3b in the vertical direction (Z-direction).

The first lower connection structures 150a and 150b may include 1-1 lower connection structures 150a disposed in the 3-1 lower region BL3a, and 1-2 lower connection structures 150b disposed in the 3-2 lower region BL3b.

The 1-1 lower connection structures 150a, together with the 1-1 intermediate connection structures 110a, may provide a transmission path for the power signal of the fourth semiconductor chip 400.

The 1-2 lower connection structures 150b, together with the 1-2 intermediate connection structures 110b, may provide a transmission path for a data signal and/or an address signal of the fourth semiconductor chip 400.

A size of the 1-1 lower connection structures 150a may be larger than a size of the 1-2 lower connection structures 150b. For example, a cross-sectional area of the 1-1 lower connection structures 150a may be larger than a cross-sectional area of the 1-2 lower connection structures 150b when viewed in plan view. However, the present disclosure is not limited thereto, and the size of the 1-1 lower connection structures 150a may be substantially the same as the size of the 1-2 lower connection structures 150b. For example, a cross-sectional area of the 1-1 lower connection structures 150a may be substantially the same as a cross-sectional area of the 1-2 lower connection structures 150b when viewed in plan view.

The fourth semiconductor chip 400 may be electrically connected to the 1-1 intermediate connection structure 110a and the 1-1 lower connection structures 150a to supply the power signal through the 1-1 intermediate connection structures 110a and the 1-1 lower connection structures 150a.

The fourth semiconductor chip 400 may be electrically connected to the 1-2 intermediate connection structures 110b and the 1-2 lower connection structures 150b to supply the data signal and/or the address signal through the 1-2 intermediate connection structures 110b and the 1-2 lower connection structures 150b.

An area of the 3-1 lower region BL3a may be smaller than an area of the 3-2 lower region BL3b. In one example, the number of 1-1 lower connection structures 150a disposed in the 3-1 lower region BL3a may be less than the number of 1-2 lower connection structures 150b disposed in the 3-2 lower region BL3b. However, the present disclosure is not limited thereto, and an arrangement and an area of the 3-1 lower region BL3a and 3-2 lower region BL3b may be changed in various ways.

The second lower region BL2 may include a 2-1 lower region BL2a and a 2-2 lower region BL2b. The 2-2 lower region BL2b, together with the 2-1 lower region BL2a, may be arranged adjacent to the third lower region BL3 in the second direction (Y-direction).

The 2-1 lower region BL2a may overlap the first semiconductor chip 300 disposed on the upper surface of the lower substrate 101 in the vertical direction (Z-direction). The 2-2 lower region BL2b may overlap the second semiconductor chip 300M disposed on the upper surface of the lower substrate 101 in the vertical direction (Z-direction).

The first lower region BL1 may be disposed on one side of the second lower region BL2. The first lower region BL1 may surround at least one side of the second lower region BL2. For example, the first lower region BL1 may surround a first side surface of the second lower region BL2 and a second side surface connected to the first side surface and extending in the first direction (X-direction).

The second lower connection structures 150c, 150d, and 150f may include a 2-1 lower connection structure 150d disposed in the 2-1 lower region BL2a, 2-2 lower connection structures 150e disposed in the 2-2 lower region BL2b, and 2-3 lower connection structures 150c disposed in the first lower region BL1.

The 2-1 lower connection structure 150d may provide a transmission path for a power signal (hereinafter referred to as a 2-1 lower signal) to the first semiconductor chip 300. The first semiconductor chip 300 may be electrically connected to the 2-1 lower connection structure 150d to supply the power signal to the first semiconductor chip 300 through the 2-1 lower connection structure 150d.

The 2-2 lower connection structure 150e may provide a transmission path for a power signal (hereinafter referred to as a 2-2 lower signal) to the second semiconductor chip 300M and the third semiconductor chip 400M. In one example, the second semiconductor chip 300M may be electrically connected to the 2-2 lower connection structures 150e to supply the power signal to the second semiconductor chip 300M through the 2-2 lower connection structures 150e. In one example, the third semiconductor chip 400M may be electrically connected to the second intermediate connection structures 110 and the 2-2 lower connection structures 150e to supply the power signal to the third semiconductor chip 400M through the second intermediate connection structures 110 and the 2-2 lower connection structures 150e.

The 2-3 lower connection structure 150c may provide a transmission path for a data signal and/or an address signal (hereinafter referred to as a 2-3 lower signal) of the first semiconductor chip 300. The first semiconductor chip 300 may be electrically connected to the 2-3 lower connection structures 150c to supply the data signal and/or the address signal to the first semiconductor chip 300 through the 2-3 lower connection structures 150c.

Sizes of the 2-1 lower connection structures 150d and the 2-2 lower connection structures 150e may be larger than a size of the 2-3 lower connection structures 150c. For example, a cross-sectional area of the 2-1 lower connection structures 150d and the 2-2 lower connection structures 150e may be larger than a cross-sectional area of the 2-3 lower connection structures 150c when viewed in plan view. However, the present disclosure is not limited thereto, and the sizes of the 2-1 lower connection structures 150d, the 2-2 lower connection structures 150e, and the 2-3 lower connection structures 150c are substantially the same as each other. For example, cross-sectional areas of the 2-1 lower connection structures 150d, the 2-2 lower connection structures 150e, and the 2-3 lower connection structures 150c may be substantially the same when viewed in plan view.

When viewed in plan view, a size of each of the lower connection structures 150 may be larger than a size of each of the first and second intermediate connection structures 110 and 120. For example, a cross-sectional area of each of the lower connection structures 150 may be larger than a cross-sectional area of each of the first and second intermediate connection structures 110 and 120. However, the present disclosure is not limited thereto, and the size of each of the lower connection structures 150 may be substantially the same as the size of each of the first and second intermediate connection structures 110 and 120. For example, a cross-sectional area of each of the lower connection structures 150 may be substantially the same as a cross-sectional area of each of the first and second intermediate connection structures 110 and 120.

The semiconductor package according to example embodiments of the present disclosure may include a first semiconductor chip (or a first logic chip) 300 on the lower substrate 101 and a third semiconductor chip (or a second memory chip) 400M on the upper substrate 201, which overlap each other in the vertical direction. Additionally, the semiconductor package may include connection structures 120, 150c, 150d, and 150f overlapping the fourth semiconductor chip 400M in the vertical direction and electrically connected to the first semiconductor chip 300 and the fourth semiconductor chip 400M to provide an electrical path for the power signal and/or the data signal. Accordingly, the semiconductor package may minimize the connection structures to which the ground signal is connected through efficient arrangement of the connection structures 120, 150c, 150d and 150f, thereby efficiently forming a signal path transmitted to the first semiconductor chip 300 and the fourth semiconductor chip 400M.

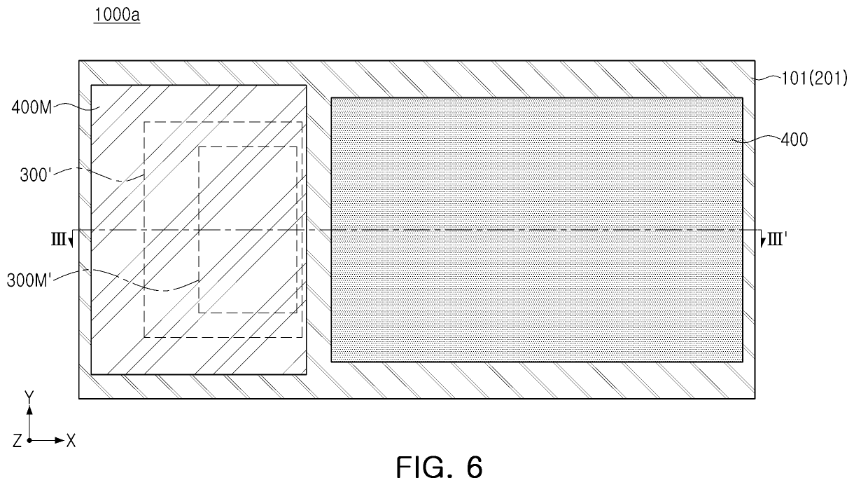

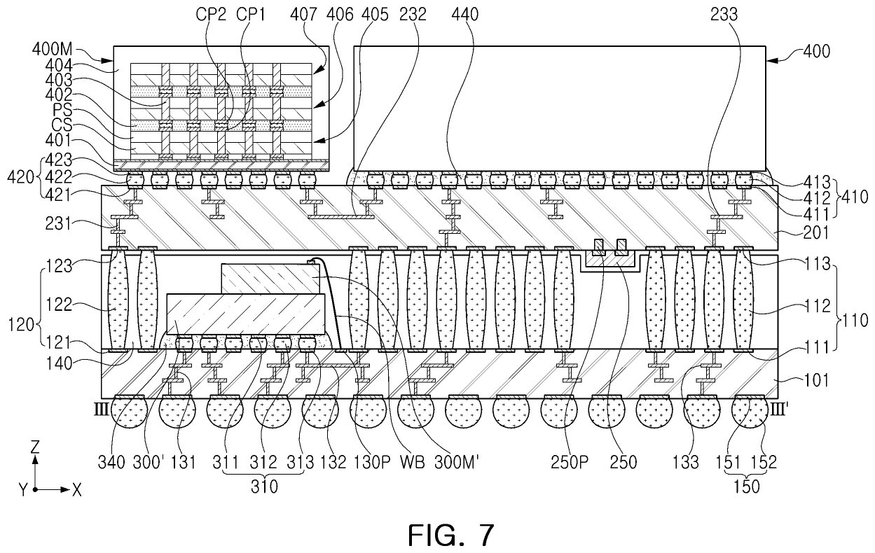

FIG. 6 is a plan view of a semiconductor package according to another example embodiment of the present disclosure. FIG. 7 is a cross-sectional view illustrating an example embodiment taken along line III-III′ of FIG. 6.

Referring to FIGS. 6 and 7, in a semiconductor package 1000a, the remaining components except a first semiconductor chip 300′ and a second semiconductor chip 300M′ may be identical or substantially the same as the components illustrated in FIGS. 1 and 2A.

The second semiconductor chip 300M′ may be disposed on an upper portion of the first semiconductor chip 300′. The first semiconductor chip 300′ and the second semiconductor chip 300M′ may overlap each other in the vertical direction (Z-direction).

The second semiconductor chip 300M′ may be disposed on the first semiconductor chip 300 and may be electrically connected to a bonding pad 130P disposed on the upper surface of the lower substrate 101 by a bonding wire WB. The bonding pad 130P, the lower connection structures 150, and a lower interconnection layer between the bonding pad 130P and the lower connection structure 150 may form an electrical path for a power signal of the second semiconductor chip 300M′.

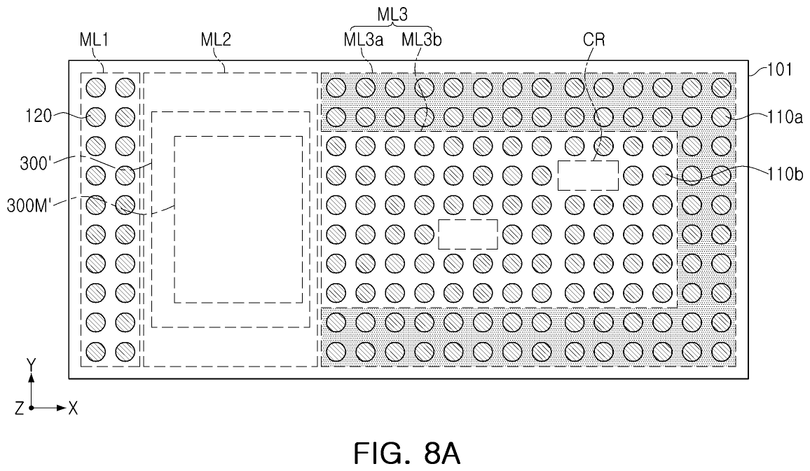

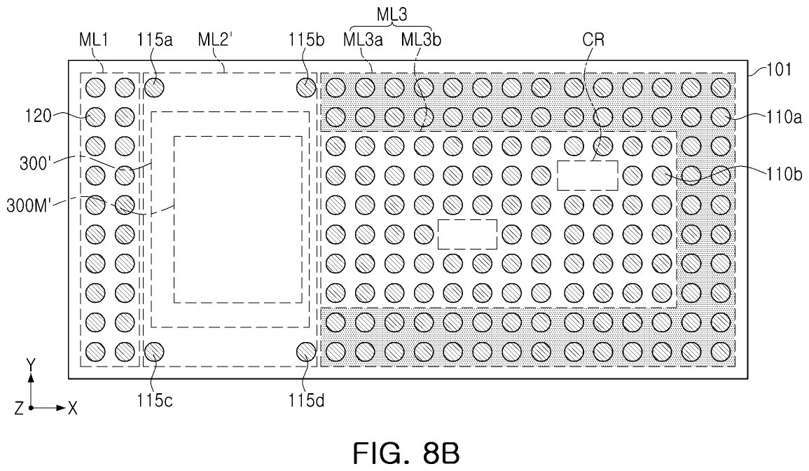

FIG. 8A is a plan view illustrating an example embodiment an array of the intermediate connection structures of FIG. 7.

Referring to FIGS. 7 and 8A, the first intermediate region ML1 may be a region in which the second intermediate connection structures 120 are disposed. The second intermediate region ML2 may be a region in which a first semiconductor chip 300′ and a second semiconductor chip 300M′ are disposed. The third intermediate region ML3 may be a region in which the first intermediate connection structures 110 are disposed.

Only the first and second semiconductor chips 300′ and 300M′ and a mold layer 140 surrounding the first and second semiconductor chips 300′ and 300M′ may be disposed between the second intermediate region ML2 of the lower substrate 101 and the upper substrate 201 overlapping the second intermediate region ML2 in the vertical direction (Z-direction), and support structures such as the intermediate connection structures 110 and 120 may not be disposed therebetween.

FIG. 8B is a plan view illustrating another example embodiment of an array of the intermediate connection structures of FIG. 7.

The remaining components except for third intermediate connection structures 115a to 115d of the semiconductor package 1000a may be identical or substantially the same as the components illustrated in FIG. 8A.

The third intermediate connection structures 115a to 115d may be disposed on the second intermediate region ML2. The third intermediate connection structures 115a to 115d may be disposed on the same level as the first and second intermediate connection structures 110 and 120 on the lower substrate 101, and may be formed in the same process as the intermediate connection structures 110 and 120.

The density of the third intermediate connection structures 115a to 115d of the second intermediate region ML2 may be smaller than the density of the second intermediate connection structures 120 on the first intermediate region ML1 and the density of the first intermediate connection structures 110 on the third intermediate region ML3.

The third intermediate connection structures 115a to 115d may be disposed in a region adjacent to an edge of the second intermediate region ML2. In one example, the third intermediate connection structures 115a to 115d may be disposed adjacent to vertices of the first semiconductor chip 300′. For example, the third intermediate connection structures 115a to 115d may include a 3-1 intermediate connection structure 115a, a 3-2 intermediate connection structure 115b, a 3-3 intermediate connection structure 115c, and a 3-4 intermediate connection structure 115d, which are disposed adjacently to the vertices of the first semiconductor chip 300′ centered on the first semiconductor chip 300′.

The third intermediate connection structures 115a to 115d of the semiconductor package 1000a are illustrated as including four intermediate connection structures, but the present disclosure is not limited thereto, and the third intermediate connection structures 115a to 115d may include four or more intermediate connecting structures, or may include four or fewer intermediate connecting structures.

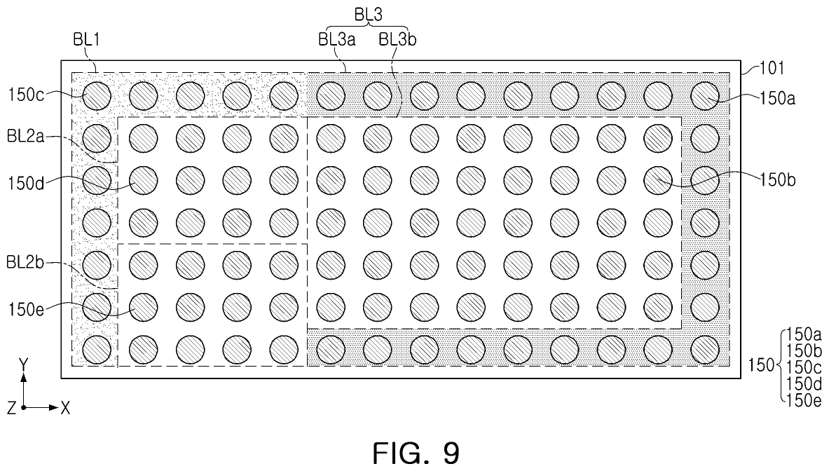

FIG. 9 is a plan view illustrating an example embodiment of an array of the lower connection structure of FIG. 8A.

Referring to FIG. 9, the lower surface of the lower substrate 101 may include a first lower region BL1, a second lower region BL2, and a third lower region BLL3, which are sequentially arranged in the first direction (X-direction).

Referring to FIGS. 8A and 9, the 2-1 lower region BL2a may overlap the first semiconductor chip 300′ and the second semiconductor chip 300M′ disposed on the upper surface of the lower substrate 101 in the vertical direction (Z-direction). The 2-2 lower region BL2b may overlap a portion of the first semiconductor chip 300′ and a portion of the second semiconductor chip 300M′. However, the present disclosure is not limited thereto, and the 2-2 lower region BL2b may not overlap the first and second semiconductor chips 300′ and 300M′ in the vertical direction (Z-direction).

The 2-2 lower connection structure 150e may provide a transmission path for a power signal to the second semiconductor chip 300M′ and the third semiconductor chip 400M. In one example, the second semiconductor chip 300M′ may be electrically connected to the 2-2 lower connection structures 150e through the bonding wire WB and the bonding pad 130P, thus supplying the power signal to the second semiconductor chip 300M′ through the 2-2 lower connection structures 150e.

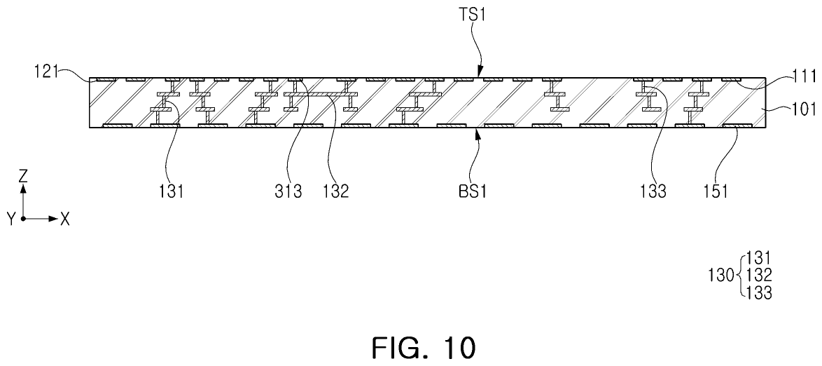

FIGS. 10 to 15 are views illustrating an example embodiment of a method of manufacturing the semiconductor package of FIG. 1.

Referring to FIG. 10, a method of manufacturing a semiconductor package may include preparing a lower substrate 101 having an upper surface TS1 and a lower surface BS1 opposing the upper surface TS1.

First intermediate lower pads 111, second intermediate lower pads 121 and first lower pads 313 may be formed on the upper surface TS1 of the lower substrate 101. The first intermediate lower pads 111 and the second intermediate lower pads 121 may be spaced apart from each other in the first direction (X-direction) with the first lower pads 313 interposed therebetween.

Lower connection pads 151 may be formed on the lower surface BS1 of the lower substrate 101. In one example, the lower connection pads 151 may overlap the first intermediate lower pads 111, the second intermediate lower pads 121, and the first lower pads 313 in the vertical direction (Z-direction).

Lower interconnection layers 130 may be formed between the first intermediate lower pads 111, the second intermediate lower pads 121, the first lower pads 313, and the lower connection pads 151.

The first lower pad 313, the lower connection pads 151, and the first lower signal pattern 131 formed between the first lower pad 313 and the lower connection pads 151 may be an electrical path of a power signal of the first semiconductor chip 300 to be described below.

The first intermediate lower pad 111, the lower connection pads 151, and the third lower signal pattern 133 formed between the first intermediate lower pad 111 and the lower connection pads 151 may be an electrical path for a power signal, a data signal, and/or an address signal of the fourth semiconductor chip 400 to be described below.

The first lower pad 313, the first intermediate lower pad 111, and the second lower signal pattern 132 formed between the first lower pad 313 and the first intermediate lower pad 111 may be an electrical path electrically connecting the first semiconductor chip 300 and the fourth semiconductor chip 400.

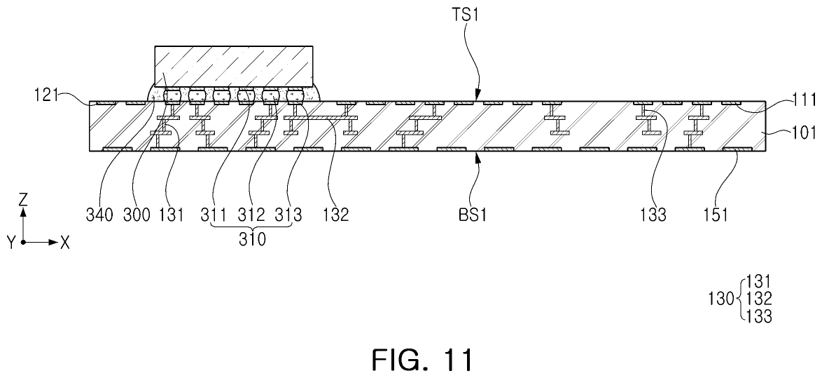

Referring to FIG. 11, a first semiconductor chip 300 may be formed on the upper surface TS1 of the lower substrate 101. The first semiconductor chip 300 may be mounted on the upper surface TS1 of the lower substrate 101 through the first connection pattern 310.

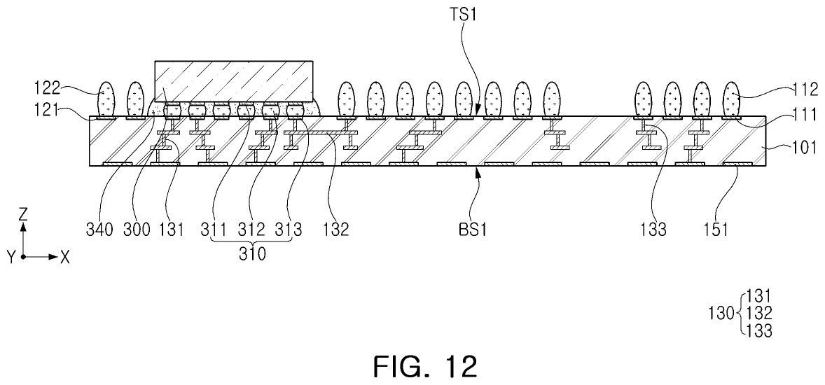

Referring to FIG. 12, first intermediate bumps 112 and second intermediate bumps 122 may be formed on the upper surface TS1 of the lower substrate 101.

The first intermediate bumps 112 and the second intermediate bumps 122 may be formed in the same process. In one example, the first intermediate bumps 112 and the second intermediate bumps 122 may be spaced apart from each other in the first direction (X-direction) with the first semiconductor chip 300 interposed therebetween.

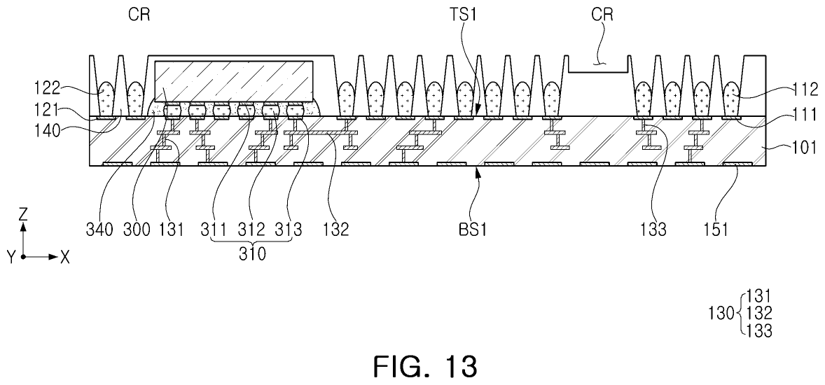

Referring to FIG. 13, a mold layer 140 may be formed on the upper surface TS1 of the lower substrate 101. The mold layer 140 may include an opening exposing at least a portion of the first intermediate bump 112 and the second intermediate bump 122. The upper surface of the mold layer 140 may include a passive device mounting region CR from which a portion of the mold layer 140 is removed in the vertical direction (Z-direction). The passive element mounting area CR may be a region in which passive elements to be disposed on the lower surface of the upper substrate 201 described below are to be disposed.

After forming the mold layer 140 on the lower substrate 101 to cover the first semiconductor chip 300, the first intermediate bumps 112 and the second intermediate bumps 122 through a molded underfill (MUF) process, the mold layer 140 may be etched through a laser drilling process (LDP) to form an opening exposing the first intermediate bumps 112 and the second intermediate bumps 122.

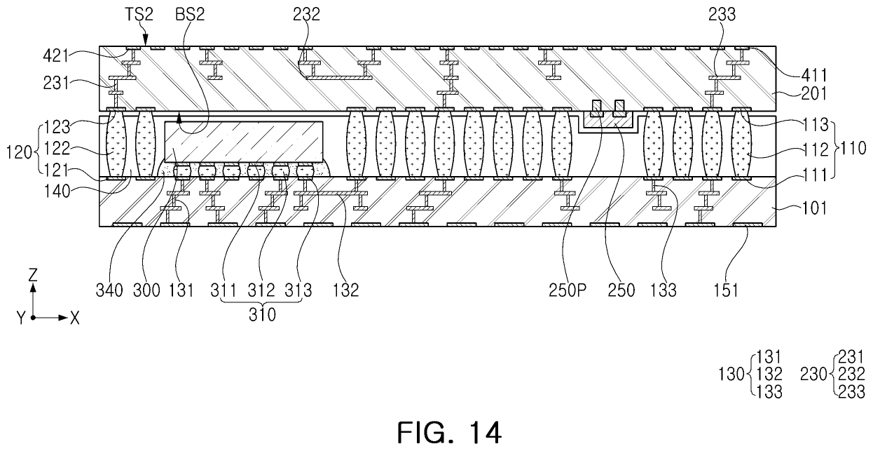

Referring to FIG. 14, the method of manufacturing a semiconductor package may include preparing an upper substrate 201 having an upper surface TS2 and a lower surface BS2 facing the upper surface TS2 on the mold layer 140.

Third lower pads 421 and fourth lower pads 411 may be formed on the upper surface TS2 of the upper substrate 201.

First intermediate upper pads 113, second intermediate upper pads 123, first intermediate bumps 112 disposed on lower surfaces of the first intermediate upper pads 113, and second intermediate bump 122 disposed on lower surfaces of the second intermediate upper pads 123 may be formed on the lower surface BS2 of the upper substrate 201.

In one example, the first intermediate bumps 112 disposed on the lower surfaces of the first intermediate upper pads 113 may be bonded to the first intermediate bumps 112 on the first intermediate lower pads 111 exposed through the opening of the mold layer 140. In one example, the second intermediate bumps 122 disposed on the lower surfaces of the second intermediate upper pads 123 may be bonded to the second intermediate bumps 122 on the second intermediate lower pads 121 exposed through the opening of the mold layer 140.

Upper interconnection layers 230 may be formed between the third and fourth lower pads 421 and 411 and the first and second intermediate upper pads 113 and 123.

The third lower pad 421, the second intermediate upper pads 123, and the first upper signal pattern 231 electrically connecting the third lower pad 421 and the second intermediate upper pads 123 may form an electrical path for a power signal of a third semiconductor chip 400M to be described below.

The fourth lower pad 411, the first intermediate upper pads 113, and the third upper signal pattern 233 electrically connecting the fourth lower pad 411 and the first intermediate upper pads 113 may form an electrical path for a power signal, a data signal, and/or an address signal of a fourth semiconductor chip 400 to be described below.

The third lower pad 421, the fourth lower pad 411, and the second upper signal pattern 232 electrically connecting the third lower pad 421 and the fourth lower pad 411 may form an electrical path for the third semiconductor chip 400M and the fourth semiconductor chip 400.

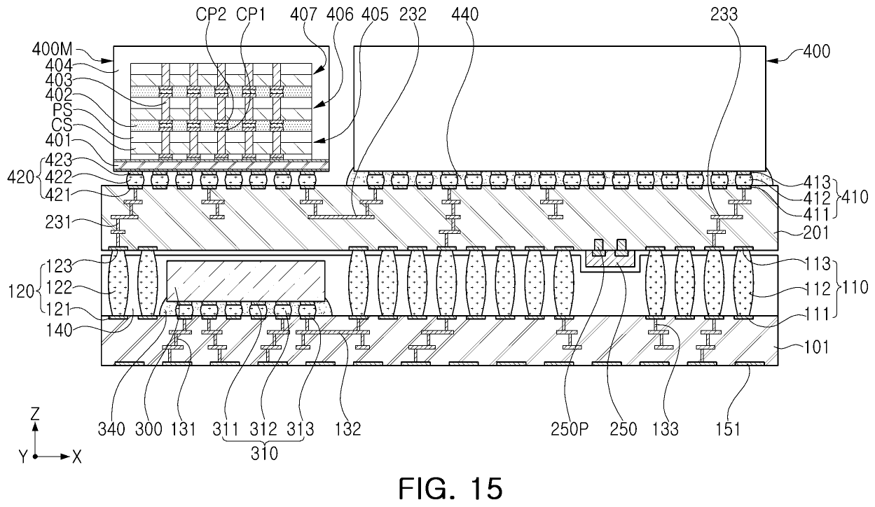

Referring to FIG. 15, the third semiconductor chip 400M may be formed on the third lower pads 421 and the fourth semiconductor chip 400 may be formed on the fourth lower pads 411. The third semiconductor chip 400M may be mounted on the upper surface TS2 of the upper substrate 201 through the third connection patterns 420. The fourth semiconductor chip 400 may be mounted on the upper surface TS2 of the upper substrate 201 through the fourth connection patterns 410.

Next, referring to FIGS. 2A and 10, lower connection bumps 152 may be formed on the lower surface BS1 of the lower substrate 101. The lower connection bumps 152 may be included in the lower connection structures 150 together with the lower connection pads 151. Accordingly, the semiconductor package 1000 may be manufactured.

While example embodiments have been illustrated and described above, it will be apparent to those skilled in the art that modifications and variations could be made within a scope not departing from the spirit and region of the present disclosure as defined by the appended claims.

What is claimed is:

1. A semiconductor package, comprising:
a lower substrate having an upper surface including a first region, a second region, and a third region sequentially arranged in a first direction, and including a lower interconnection layer;
lower connection structures disposed below the lower substrate;
a first semiconductor chip disposed on the second region and electrically connected to the lower interconnection layer;
a second semiconductor chip adjacent to the first semiconductor chip on the second region and electrically connected to the first semiconductor chip;
intermediate connection structures disposed on the lower substrate and electrically connected to the lower interconnection layer;
an upper substrate disposed on the first semiconductor chip and the intermediate connection structures;
a third semiconductor chip overlapping the first semiconductor chip on the upper substrate in a perpendicular direction, which is perpendicular to an upper surface of the first semiconductor chip; and
a fourth semiconductor chip spaced apart from the third semiconductor chip on the upper substrate in the first direction and overlapping the third region in the perpendicular direction,
wherein a density of the intermediate connection structures disposed on the first region and the third region is greater than a density of the intermediate connection structures disposed on the second region.

2. The semiconductor package of claim 1, wherein the intermediate connection structures are not disposed in the second region.

3. The semiconductor package of claim 1,
wherein the intermediate connection structures include first intermediate connection structures disposed in the third region and electrically connected to the fourth semiconductor chip, and
wherein the first intermediate connection structures include:
first-first intermediate connection structures configured to provide a transmission path for a first-first intermediate signal; and
second-first intermediate connection structures configured to provide a transmission path for a second-first intermediate signal different from the first-first intermediate signal, and surrounding at least one side of the first-first intermediate connection structures.

4. The semiconductor package of claim 3, wherein the intermediate connection structures include second intermediate connection structures disposed on the first region and configured to provide a transmission path for a second intermediate signal electrically connected to the third semiconductor chip.

5. The semiconductor package of claim 4, wherein the second intermediate connection structures are not electrically connected to the first and second semiconductor chips.

6. The semiconductor package of claim 4,
wherein the intermediate connection structures further include third intermediate connection structures disposed in the second region, and
wherein a gap between the third intermediate connection structures is greater than a gap between the first intermediate connection structures and a gap between the second intermediate connection structures.

7. The semiconductor package of claim 3,
wherein the lower connection structures include first lower connection structures electrically connected to the fourth semiconductor chip overlapping the third region, and
wherein the first lower connection structures include:
first-first lower connection structures electrically connected to the first-first intermediate connection structures; and
second-first lower connection structures surrounding at least one side of the first-first lower connection structures and electrically connected to the second-first intermediate connection structures.

8. The semiconductor package of claim 7,
wherein the lower connection structures further include second lower connection structures overlapping each other in the perpendicular direction, which is perpendicular to the first region and the second region, and
wherein the second lower connection structures include:
first-second lower connection structures overlapping the first semiconductor chip in the perpendicular direction, electrically connected to the first semiconductor chip, and configured to provide a transmission path for a first-second lower signal, and
second-second lower connection structures overlapping the second semiconductor chip in the perpendicular direction, electrically connected to the second semiconductor chip and the third semiconductor chip, and configured to provide a transmission path for a second-second lower signal different from the first-second lower signal.

9. The semiconductor package of claim 8, wherein the second lower connection structures further include third-second structures surrounding at least one side of the first-second lower connection structures and the second-second lower connection structures, electrically connected to the first semiconductor chip, and configured to provide a transmission path for a third-second lower signal different from the first-second lower signal.

10. The semiconductor package of claim 1,
wherein an area of the first region is smaller than an area of the second region and an area of the third region, and
wherein the area of the third region is larger than the area of the second region.

11. The semiconductor package of claim 1, further comprising:
a mold layer surrounding side surfaces of the intermediate connection structures, the first semiconductor chip, and the second semiconductor chip on the lower substrate.

12. The semiconductor package of claim 1,
wherein the first semiconductor chip includes a communication processor (CP) chip,
wherein the second semiconductor chip includes a first memory chip electrically connected to the first semiconductor chip,
wherein the third semiconductor chip includes a second memory chip electrically connected to the fourth semiconductor chip, and
wherein the fourth semiconductor chip includes an application processor (AP) chip.

13. The semiconductor package of claim 1, further comprising:
a capacitor disposed on a lower surface of the upper substrate and overlapping the third region in the perpendicular direction.

14. A semiconductor package, comprising:
a lower substrate including a lower interconnection layer;
lower connection structures disposed below the lower substrate;
a first semiconductor chip disposed on the lower substrate and electrically connected to the lower interconnection layer;
first intermediate connection structures disposed on one side of the first semiconductor chip on the lower substrate and configured to provide a transmission path for a first signal;
second intermediate connection structures disposed on the other side, opposing the one side of the first semiconductor chip on the lower substrate and configured to provide a transmission path for a second signal different from the first signal;
an upper substrate disposed on the first semiconductor chip, the first intermediate connection structures, and the second intermediate connection structures;
a third semiconductor chip overlapping the first semiconductor chip on the upper substrate in a perpendicular direction, which is perpendicular to the first semiconductor chip, and electrically connected to the first intermediate connection structures; and
a fourth semiconductor chip spaced apart from the third semiconductor chip on the upper substrate in a first direction, intersecting the perpendicular direction, and electrically connected to the second intermediate connection structures,
wherein the first intermediate connection structures and the second intermediate connection structures are spaced apart from each other in the first direction with the first semiconductor chip interposed therebetween.

15. The semiconductor package of claim 14, further comprising:
a second semiconductor chip spaced apart from the first semiconductor chip on the lower substrate, in a second direction, intersecting the first direction and the perpendicular direction.

16. The semiconductor package of claim 14, further comprising:
a second semiconductor chip disposed directly on the first semiconductor chip and electrically connected to the lower interconnection layer through wire bonding.

17. The semiconductor package of claim 14, wherein the lower connection structures include:
first lower connection structures overlapping the second intermediate connection structures in the perpendicular direction, and electrically connected to the fourth semiconductor chip and the second intermediate connection structures;
second lower connection structures overlapping the first semiconductor chip in the perpendicular direction, and configured to provide a transmission path for a power signal of the first semiconductor chip; and
third lower connection structures overlapping the second intermediate connection structures in the perpendicular direction, surrounding at least one side of the second lower connection structure, and configured to provide a transmission path for a data signal of the first semiconductor chip.

18. The semiconductor package of claim 14, wherein a height of the upper substrate in the perpendicular direction is greater than a height of the lower substrate in the perpendicular direction.

19. A semiconductor package, comprising:
a lower substrate having an upper surface including a first region, a second region, and a third region sequentially arranged in a first direction, and including a lower interconnection layer;
a first logic chip disposed on the second region and electrically connected to the lower interconnection layer;
a first memory chip spaced apart from the first logic chip in the second region and electrically connected to the first logic chip;
intermediate connection structures disposed on the lower substrate and electrically connected to the lower interconnection layer;
an upper substrate disposed on the first logic chip and the intermediate connection structures;
a second memory chip overlapping the first logic chip on the upper substrate in a direction, perpendicular to the first logic chip; and
a second logic chip spaced apart from the second memory chip on the upper substrate in the first direction, and electrically connected to the second memory chip,
wherein the intermediate connection structures include first intermediate connection structures disposed on the third region and electrically connected to the second logic chip, and second intermediate connection structures spaced apart from the first intermediate connection structures on the first region in the first direction and electrically connected to the second memory chip.

20. The semiconductor package of claim 19, wherein the intermediate connection structures are not disposed in the second region.
